(19) United States
(12) Patent Application Publication
(10) Pub. No.: US 2026/0254202 A1
(43) Pub. Date: Aug. 27, 2026

(54) ULTRA-WIDE TUNABLE LASER SOURCE WITH MULTI-BAND GAIN MEDIA INTEGRATION

(71) Applicant: GouMax Technology, Inc., Milpitas, CA (US)

(72) Inventors: Yung-Chieh Jay Hsieh, San Jose, CA (US); Dejin Yu, Fremont, CA (US)

(73) Assignee: GouMax Technology, Inc., (US)

(21) Appl. No.: 19/530,212

(22) Filed: Feb. 4, 2026

Related U.S. Application Data
(60) Provisional application No. 63/761,945, filed on Feb. 22, 2025.

(51) Int. Cl. H01S 5/14; H01S 5/10; H04J 14/06

(52) U.S. Cl. CPC H01S 5/143; H01S 5/1071; H04J 14/06

(57) ABSTRACT

A tunable laser system includes a plurality of gain media arranged in a plurality of optical paths; an optical device configured to combine optical signals from the gain media into a common optical cavity path shared by the gain media, using at least one optical multiplexing mechanism selected from wavelength-division multiplexing or polarization-division multiplexing; a wavelength-selective tunable filter disposed in the common optical cavity path to select a lasing wavelength; a feedback path configured to return at least a portion of a filtered optical signal from the common optical cavity path to at least one selected gain medium to sustain lasing; and a controller configured to selectively activate at least one gain medium corresponding to the selected lasing wavelength. The plurality of gain media can function as a single effective gain medium providing a tunable wavelength range exceeding that of any individual gain medium among the plurality of gain media.

### CROSS-REFERENCE TO RELATED APPLICATION

The present disclosure claims benefits of U.S. Provisional Patent Application No. 63/761,945 filed on Feb. 22, 2025, the disclosure of which is hereby incorporated by reference in its entirety.

### BACKGROUND

Tunable lasers are important components in a wide variety of optical systems, such as optical coherence tomography (OCT), spectroscopy, optical frequency domain reflectometry (OFDR), telecommunications, test and measurement of optical components, etc.

### SUMMARY

The present disclosure relates generally to tunable laser sources, and more specifically to tunable lasers configured to provide an expanded wavelength tuning range.

In some embodiments, a laser source is provided that includes a plurality of gain media arranged in parallel, each associated with a wavelength zone. Output light from these parallel gain media can be combined into a single optical beam using wavelength division filters and/or a polarization beam combiner (PBC). The combined system of gain media can be referred to as an Effective Gain Medium (EGM) with a wavelength coverage that represents a union of the individual gain media's spectral ranges.

A controller can be configured to selectively activate one or more of the gain media. By integrating the EGM with a tunable filter, a tunable laser source can be constructed with a wavelength tuning range that is significantly broader than that of any individual gain medium.

In some embodiments, only one gain medium is activated at a time based on the desired lasing wavelength. Each gain medium may be a semiconductor device configured to emit light in response to an injected electrical current.

The wavelength zones corresponding to different gain media may be distinct or partially overlapping. The gain media may be interconnected via one or more optical paths, which can include, e.g., polarization-maintained (PM) fibers, free-space coupling, or other types of interconnects.

The system can further include structures and/or components configured to adjust an intensity and a phase of an optical signal from the active gain medium to control the final beam characteristics. In some configurations, long-pass filters can be employed to direct optical signals from odd and even wavelength zones into separate channels, which are then recombined via the PBC. The PBC can be configured to transmit P-polarized light and reflect S-polarized light, enabling clean integration of signals from distinct gain paths.

In some embodiments, a dual-band tunable laser is provided, wherein two gain media cover distinct wavelength ranges. For example, P-polarized light from a first gain medium and S-polarized light from a second gain medium are combined through a PBC into a single optical path. A tunable filter selects the desired lasing wavelength, while a feedback loop directs a portion of the filtered light back to the active gain medium for amplification. This configuration can achieve a wavelength tuning range approximately twice that of a single-band system.

In some embodiments, a quadruple-band tunable laser incorporates four gain media, each associated with a specific wavelength zone. A first long-pass filter is employed to merge light corresponding to odd-numbered zones, such as zone-1 and zone-3, which are P-polarized. A second long-pass filter is employed to merge light corresponding to even-numbered zones, such as zone-2 and zone-4, which are S-polarized. Such two orthogonally polarized light beams can then be combined into a common optical path through a PBC. A tunable filter can be positioned in a common optical path to select a wavelength for laser output. In an example, the design allows for wavelength tuning over a range from approximately 1250 nm to 1650 nm in the near-infrared region. In various embodiments, one or more long-pass filters may be substituted with one or more short-pass filters or bandpass filters. Those filters are, in general, belonging to WDM filters (Wavelength Division Multiplexing). They are used to combine (MUX) or split (De-MUX) light signals with different wavelengths.

In some embodiments where more than four gain media are employed, odd-numbered wavelength zones can be combined into a P-polarized channel, and even-numbered zones can be into an S-polarized channel. Such two channels can be merged by a PBC and pass through a common tunable filter to select a wavelength. Long-pass filters and polarization beam splitters can be utilized within the cavity loop to route feedback light to the corresponding amplifier for regeneration.

The tunable laser source, according to some embodiments of the present disclosure, can provide a scalable method for extending the tuning range of wavelength-swept lasers. By combining multiple gain media, employing advanced filtering schemes, and managing polarization states carefully, the system enables efficient and broad tunability for applications including optical coherence tomography, spectroscopy, and fiber sensing.

### BRIEF DESCRIPTION OF THE DRAWINGS

FIG. 1 illustrates a diagram of a semiconductor external cavity diode laser (ECDL), the Littman-Metcalf configuration tunable laser based on a diffraction grating. In this configuration, the combination of diffraction grating and the rotation mirror functions as a tunable filter configured to select a wavelength.

FIG. 2 illustrates a schematic diagram of a tunable ring laser system. The tunable filters utilized in such systems can be implemented using various technologies, such as those based on grating, a Fabry-Perot etalon, or a thin-film filter.

FIG. 3 illustrates a schematic diagram of a dual-band tunable ring Laser with two gain media to cover two consecutive bands of wavelengths.

FIG. 4 illustrates a schematic structure of one embodiment of a long-pass filter based on a thin-film interference coating design.

FIG. 5 illustrates a quadruple-band tunable laser ring with four gain media to cover four consecutive bands of wavelength.

FIG. 6 illustrates a transmission spectrum of a long-path filter with four gain media.

FIG. 7 illustrates a tunable ring Laser with more than four gain media to cover multiple consecutive wavelength bands.

FIG. 8 illustrates a transmission spectrum of a long-path filter with more than four gain media.

FIG. 9 illustrates a method of tuning laser wavelengths by selectively activating parallel gain media, and combining light emitted from different gain media utilizing optical filters and polarization beam combiners.

FIG. 10 illustrates diagrams of a basic laser structure, a dual-band laser, a four-gain-media configuration, and a multi-band laser system.

### DETAILED DESCRIPTION

Many applications can benefit from laser sources that can sweep across a broad spectrum of wavelengths while maintaining high stability, narrow linewidth, and fast tuning speeds to meet the performance requirements of precision imaging, sensing, and data transmission. Conventional tunable lasers, such as external cavity diode lasers, rely on mechanically adjusting optical components such as diffraction gratings or filters to achieve wavelength tunability, which can constrain the spatial resolution in applications such as OCT, or limit flexibility in systems requiring extensive spectral coverage.

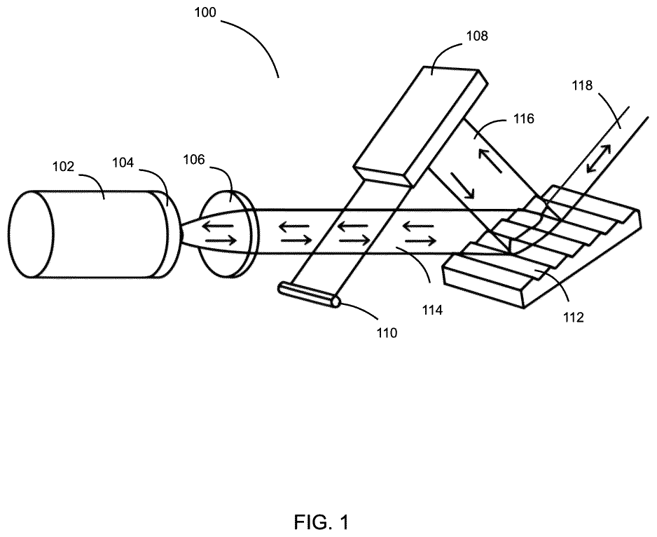

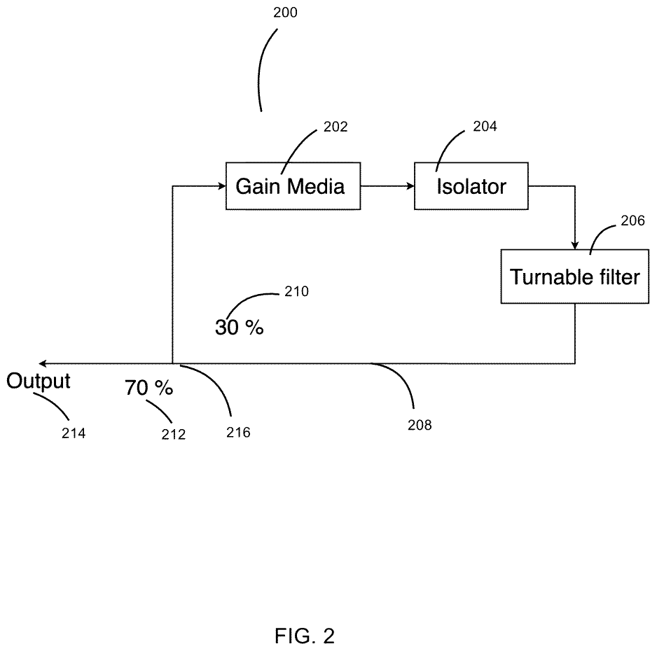

A laser operates on the principle of light amplification by stimulated emission of radiation. This process begins with a gain medium, which is a material containing a large number of electrons in high-energy states. When these electrons transition to lower energy states, they emit photons. In a laser, this emission is stimulated by incoming photons, leading to a cascade of photon emissions that amplify light. For a standing-wave type of laser source (see, e.g., FIG. 1), the gain medium is placed between two reflective surfaces, typically mirrors, forming an optical cavity. This configuration allows photons to bounce back and forth, stimulating further emissions and amplifying the light within the cavity. For a ring Laser, the gain medium is placed in the ring structure (see, e.g., FIG. 2), and a coupler is utilized to direct a portion of light back to the gain medium as feedback for amplification.

A tunable laser is a type of laser with output wavelengths adjustable over a certain range. Typical tunable lasers include dye lasers, semiconductor lasers, and titanium-sapphire lasers. Traditional tunable laser systems, particularly those with narrow-band wavelength capabilities, face several limitations that can impact their performance and applicability in various fields. These limitations primarily arise from the inherent design and operational constraints of the laser technology used.

Traditional tunable lasers may have restricted tuning range. Typically, the tuning range is constrained by the bandwidth of the gain medium, which is often around 10% of its central wavelength. The tuning range sets an upper bound on the spatial resolution for Optical Frequency Domain Analysis (OFDA) application, which is a technique used for optic sensing, such as measuring strain and temperature along an optical fiber.

For instance, if a tunable laser is configured to sweep a wavelength range from 1500 to 1650 nm, which corresponds to a spectral range of approximately 18 THz, the spatial resolution is approximately 8 μm. For certain applications, a spatial resolution of 8 μm may be insufficient. To enhance the spatial resolution, the tuning range has to be increased. Such applications may include, but not limited to, measuring defects in the semiconductor chips and the critical dimension testing in various optical components, such as the thickness of the waveplate or wafer.

To facilitate a more concise and accurate description of the system, a concept of an Effective Gain Medium (EGM) is provided according to some embodiments of the present disclosure. In such a laser system, a plurality of gain media can be disposed in a parallel arrangement, each configured to amplify light along a respective optical path. The emission from each gain medium is directed through an optical combining module to generate a single, unified output beam. Despite of comprising several discrete gain structures, the EGM functions as a single, unified gain medium from the perspective of the laser system. Accordingly, this configuration is referred to as an EGM. The EGM concept can simplify system representation and enables more scalable laser architectures while preserving key optical characteristics such as gain, feedback, and mode stability.

According to some embodiments of the present disclosure, a plurality of gain media having different wavelengths can be integrated to achieve an ultra-wide wavelength tuning range. The system includes polarization-maintained optical fibers, polarization beam combiners (PBC), polarization beam splitters (PBS), WDM filters such as long-pass (LP), short-pass (SP), or band-pass (BP) filters, and wavelength-selective elements such as tunable filters. By selectively activating one gain medium at a time and managing the optical paths of each gain media the disclosed system significantly extends the tuning range beyond the constraints of single-gain-medium designs, while maintaining compactness, stability, and operational simplicity.

In this embodiment, P or S states for PBC or PBS are referring to 2 orthogonal polarization states. PBC are used to combine these the light signals with these 2 states into a single output signal and PBS are used to separate the light signals with both S and P components into 2 outputs signals.

In the context of multi-band laser systems according to some embodiments of the present disclosure, PBCs integrate light from two different sets of gain media, with orthogonal states of polarization (e.g., P and S), into a common optical path that contains a tunable filter. For instance, light from one set of gain media can be oriented to be P-polarized, while light from another set can be S-polarized.

The PBC combines such P and S components into a single fiber or free-space path, allowing the system to utilize a single tunable filter to select the desired lasing wavelength. This integration helps to achieve ultra-wide tuning ranges, as it enables the laser to cover multiple wavelength zones by switching between different gain media.

Using PBS and PBC in optical systems according to some embodiments of the present disclosure can have one or more of the following advantages.

For example, by controlling the polarization states, PBS and PBC can enable efficient routing and combining of light.

In addition, in laser systems, the ability to separate and combine light based on polarization helps maintain stable operation by ensuring that feedback is directed to the appropriate gain media. This reduces interference and enhances the overall stability of the laser output.

PBS and PBC allow for flexible system designs, enabling the integration of multiple gain media and the extension of tuning ranges.

By maintaining the polarization state of light, these components help preserve the quality of the optical signal, which can be important for high-precision measurements and imaging applications.

Polarization-Maintaining (PM) fibers are specialized optical fibers that preserve the polarization state of light as it travels through them, preventing the usual polarization scrambling seen in standard single-mode fibers. This feature can be employed in applications where maintaining the light's polarization is important, such as in systems using PBC and PBS. These components employ specific polarization states, such as P-polarized or S-polarized light. In some other embodiments, other polarization states can be employed.

In some embodiments of the present disclosure, a laser source with an ultra-wide tunable wavelength range is achieved by integrating multiple gain media within a laser system, wherein the gain media are positioned in parallel within the optical paths. In some embodiments, each wavelength has its own specific ring cavity, and these cavities are overlapping between PBC and PBS. In some embodiments, there are multiple optical paths, each one corresponding to a gain medium. In some embodiments, only one gain medium is active at any given time. Wavelengths in odd-numbered zones can be combined using filters to form “odd” channels, and wavelengths emitted from gain media in even-numbered zones can be combined using filters to form the “even” channels. For example, the odd channels are P-polarized, and the even channels are S-polarized. A PBC is used to merge the odd channels and even channels into a common optical path, and a PBS is employed to separate the odd channels from the even channels.

Various embodiments of the present disclosure can employ modular and scalable architecture, allowing the wavelength-swept laser to be tailored for specific operational requirements. The system can be configured with two, three, four, or more gain media to accommodate diverse application needs, including optical coherence tomography (OCT), optical frequency domain reflectometry (OFDR), spectroscopy, fiber optic sensing, etc.

By integrating multiple gain media through wavelength-division multiplexing/demultiplexing and polarization-based beam combining and separation techniques, the laser system represents a transformative advancement in tunable laser technology, paving the way for high-resolution imaging, sensing, and measurement applications across scientific, industrial, and medical fields.

Illustrative embodiments of the system and methods of operation are described herein. It should be understood that in the development of any specific embodiment, numerous implementation-specific decisions may be made to achieve a developer's particular objectives, such as optimizing system performance, minimizing optical losses, and aligning with application-specific constraints, which may differ across various implementations.

As such, the embodiments described are not intended to limit the scope of the disclosure but rather to provide examples of how the disclosure can be implemented. These examples are provided to illustrate potential applications and should not be construed as exhaustive or limiting. Variations and modifications may be made without departing from the spirit and scope of the disclosure. Therefore, the disclosure should be considered broadly applicable, with potential for adaptation to suit different system designs and application requirements. The claims present are intended to define the scope of the disclosure, and any modifications or variations that fall within the boundaries of these claims are considered to be within the scope of the disclosure.

The systems and methods of use are comprehensible in terms of both structure and operation, as revealed by the accompanying drawings and the detailed description provided herein. Multiple embodiments of the system are disclosed, and it is to be understood that various components, parts, and features of these different embodiments may be combined and/or interchanged, all within the scope of the present application. Although not all variations and specific embodiments are depicted in the drawings, the mixing and matching of features, elements, and/or functions among various embodiments are expressly contemplated.

Various embodiments of the present disclosure enable one of ordinary skill in the art to appreciate that features, elements, and/or functions of one embodiment may be incorporated into another embodiment as deemed appropriate, unless otherwise specified. The embodiments described herein are not intended to be exhaustive or to limit the disclosure to the precise form disclosed. Rather, they are selected and described to elucidate principles of the disclosure and their applications and practical uses, thereby enabling others skilled in the art to follow its teachings. It should be understood that modifications and variations can be made without departing from the spirit and scope of the disclosure. The disclosure is intended to cover all such alternatives, modifications, and equivalents as may be included within the scope of the claims.

In a laser system, the gain medium can be created using various materials. In this embodiment, we use electrically pumped semiconductor material to illustrate the idea. These lasers often use compounds from elements in columns III and V of the periodic table, such as indium phosphide or gallium arsenide, as the gain medium. These materials are chosen for their ability to operate efficiently in the near-infrared spectrum, typically around 1310 nm or 1550 nm.

The laser's longitudinal modes are determined by its optical cavity, resonating at wavelengths defined by the cavity's length and the speed of light within the gain medium. A laser typically supports many longitudinal modes, and a tunable filter is used to select a specific subset of these modes, e.g., either a single mode for single-mode lasing or multiple modes for multi-mode lasing. In semiconductor lasers, the cavity length can be adjusted mechanically or by changing the refractive index of the gain medium, often through temperature changes or current injection.

There are multiple types of lasers, each with unique characteristics. For instance, distributed feedback (DFB) lasers incorporate a diffraction grating along the length of the gain medium. This grating reflects a single wavelength into the cavity, forcing a single resonant mode and producing a stable, narrow-bandwidth output. DFB lasers are tuned by controlling the temperature of the laser diode cavity, but their tuning range is limited to a few nanometers. To achieve wider tuning ranges, multiple laser cavities can be integrated into a single device.

Tunable lasers, such as those used in optical communication systems, offer significant advantages over fixed-wavelength lasers. They allow for dynamic reconfiguration of optical networks, enabling more flexible bandwidth provisioning and reducing the need for extensive inventories of spare parts. These lasers can be tuned across a range of wavelengths, making them ideal for applications such as wavelength-division multiplexing (WDM) network, where multiple wavelengths are used to carry data over a single optical fiber.

Tunable lasers have a wide array of applications due to their ability to adjust wavelengths dynamically, making them invaluable in various optical technologies. Various embodiments of the present disclosure can be applied in Optical Coherence Tomography (OCT), Optical Frequency Domain Reflectometry (OFDR), and telecommunications. In OCT, tunable lasers provide high-resolution imaging for medical diagnostics. In OFDR, they enable precise measurements of fiber optic networks. In telecommunications, they facilitate dynamic wavelength allocation for efficient data transmission.

Frequency-Domain OCT involves the use of tunable lasers in a high-resolution imaging technique primarily utilized in medical diagnostics. OCT employs coherent near-infrared light to obtain micrometer-level depth-resolved images of biological tissues. The implementation of tunable lasers facilitates the acquisition of spectral interferograms, which are subsequently Fourier transformed to derive an axial scan of reflectance amplitude versus depth. This capability is beneficial in, e.g., ophthalmology, for retinal imaging and in cardiology for coronary artery imaging, providing detailed cross-sectional images of tissues. The high resolution and non-invasive nature of OCT render it a preferred method for diagnosing and monitoring various medical conditions, including macular degeneration, diabetic retinopathy, and glaucoma, as well as for guiding surgical interventions.

In optical networks, tunable lasers can be used for spectrum scanning of passive components to ensure optimal performance and compatibility. By adjusting the laser's wavelength, it is possible to test the response of various optical components across a wide range of wavelengths. This capability can be important for the development and maintenance of wavelength-division multiplexing (WDM) systems, where multiple wavelengths are used to carry data over a single optical fiber. Tunable lasers according to embodiments of the present disclosure can help identifying and troubleshooting issues related to wavelength-specific losses or reflections in the network, thereby enhancing the reliability and efficiency of optical communication systems.

In some embodiments according to the present disclosure, tunable lasers are integrated into OFDR systems, which are used for high-resolution distributed sensing and characterization of optical fibers. In OFDR, a tunable laser source is used to sweep across a range of frequencies, and the interference pattern between the reference and measurement paths is analyzed to determine the position and characteristics of scatterers along the fiber. This technique is particularly useful for detecting and locating faults, measuring strain, and monitoring temperature changes in optical fibers. The ability to perform precise measurements over long distances makes OFDR a valuable tool in telecommunications and industrial applications.

Tunable lasers can also be highly effective in spectroscopic sensing applications, where they are used to identify and quantify various substances based on their spectral signatures. By sweeping across a range of wavelengths, tunable lasers can interact with specific molecular bonds, such as C—H, N—H, and O—H, which have unique absorption spectra. This capability allows for precise detection and analysis of chemical compositions in various environments, including industrial processes, environmental monitoring, and medical diagnostics. The ability to perform real-time analysis with high sensitivity makes tunable lasers ideal for applications such as gas detection, where they can identify trace amounts of pollutants or hazardous gases in the atmosphere.

In Light Detection and Ranging (LIDAR) systems, tunable lasers can be used for distance measurement and mapping applications. The ability to adjust the wavelengths allows for enhanced resolution and accuracy in detecting objects and measuring distances. This is particularly useful in autonomous vehicles, where LIDAR systems can be employed to create detailed 3D maps of the surroundings, enabling the vehicle to navigate safely. Tunable lasers improve the system's ability to distinguish between different surfaces and materials, enhancing the overall performance of LIDAR technology in various environmental conditions.

In some embodiments, tunable lasers can be used in secure face recognition systems, where precise wavelength control is crucial for accurate biometric identification. By using specific wavelengths that penetrate the skin, these systems can capture detailed sub-surface facial features, providing an additional layer of security beyond traditional surface-level imaging. This technology can be valuable in security and surveillance applications, where high accuracy and reliability are important.

In the pharmaceutical industry, tunable lasers can be used for quality control and process monitoring. They can analyze the chemical composition of pharmaceutical products, ensuring consistency and compliance with regulatory standards. Tunable lasers can be employed in the inspection of tablet coatings, where they help detect defects and ensure uniformity. Their ability to provide non-destructive testing makes them an invaluable tool in maintaining the quality and safety of pharmaceutical.

Tunable lasers according to embodiments of the present disclosure can also be deployed in material characterization, where they are used to study the properties of materials at different wavelengths, particularly important in research and development, where understanding the optical properties of new materials can lead to innovations in fields such as photonics and nanotechnology. Tunable lasers allow researchers to explore the interactions between light and materials, providing insights into their structure and behavior.

The flexibility and precision offered by tunable lasers make them indispensable in advancing optical technologies, enhancing the capabilities of diagnostic imaging, improving network management, and enabling sophisticated sensing applications. These applications demonstrate the versatility and importance of tunable lasers in advancing technology across various fields. Their ability to provide precise control over wavelength and intensity makes them an indispensable tool in both scientific research and practical applications.

FIG. 1 illustrates a diagram of a semiconductor external cavity diode laser (ECDL) configured in the Littman-Metcalf cavity configuration. The ECDL laser system 100 is designed to achieve wavelength tuning through mechanical adjustments of the laser cavity. This configuration includes several components that work in concert to produce a tunable laser output.

The laser diode light source 102 emits broadband light, encompassing multiple wavelengths. This emitted light beam is initially divergent and requires collimation to ensure that it travels in parallel rays. The collimating lens 106 is configured to perform this function, transforming the divergent light into a collimated beam 114 that can be effectively manipulated by subsequent optical components.

An anti-reflective coating 104 can be applied to the laser diode to minimize unwanted reflections. Collimated light beam 114 hits the grating and diffracts different wavelength components into different directions. Among the diffracted light, only one direction of light is perpendicular to the end mirror 180, and retro-reflected back to the gain media as feedback.

The reflection mirror 108 can be rotated along a pivot axle 110. By adjusting the angle of the mirror, specific wavelengths can be selected to be fed back into the laser diode. The wavelength that is fed back resonates within the laser cavity, resulting in amplification. The tuned wavelength light beam 116 is thereby determined by the angle of the mirror 110, allowing for precise control over the output wavelength.

The output beam 118 represents the laser output, which is the result of the selected wavelength being amplified within the laser cavity. The ECDL system utilizes a mechanical tuning via the Littman-Metcalf configuration to achieve a wider tuning range.

FIG. 2 illustrates a schematic diagram of a tunable ring laser system 200, with only one gain medium shown for illustration purposes. This system can include gain medium 202, which can be an effective gain medium comprising multiple gain media, as illustrated in other drawings and described in detail below, isolator 204, tunable filter 206, and feedback coupler 216, all interconnected by optical fiber. The gain medium 202 is configured to generate broadband spontaneous emission, while the optical isolator 204 ensures unidirectional propagation of light within the ring. It is noted that the direction does not necessarily represent a preferred direction. The tunable filter 206 is strategically positioned to select a narrow wavelength band for lasing, and the feedback loop 208 facilitates the amplification process by directing a portion of the light back into the gain media.

The feedback component, such as a 30/70 beam splitter, is realized by the optical coupler, specifically the feedback coupler. The optical coupler or fiber coupler is a passive optical device that splits or combines light beams. In the laser system, a beam splitter is configured to split a portion of light to the output path and direct the remaining portion of light back to the gain media for amplification. The tunable filter may be positioned before or after the feedback coupler, depending on the specific design. In the current embodiment, the tunable filter is placed before the feedback coupler. In this diagram, 30% of the optical power is used to maintain the population inversion necessary for continuous laser emission. 70% of the optical power is directed to the Laser output. Accordingly, the block may be referred to as a 30/70 beam splitter.

While 30% branch 210 directs a portion of the light back into the gain medium for further amplification, and 70% branch 212 serves as the output 214 of the tunable laser. This output-to-feedback ratio can be adjusted based on specific design requirements to optimize performance. The tuning range of this structure is primarily determined by the bandwidth of the gain medium, which will be significantly extended through the use of multiple gain media arranged in parallel in later designs. Additionally, the use of advanced wavelength-selective elements, such as diffraction gratings or etalons, can further refine the tuning precision and stability.

The tunable filter 206 selects the desired lasing wavelength from the combined optical signal in the common path. It is configured to selectively pass a narrow wavelength band, which is then amplified by the active gain medium. The feedback loop 208, incorporating the feedback coupler 216, splits the filtered light into an output path and a feedback path, directing a portion of the light back to the active gain medium for amplification.

Traditional tunable laser sources, particularly those based on semiconductor external cavity designs, face a fundamental limitation in their achievable wavelength tuning range. This constraint arises directly from the inherent bandwidth a single gain medium, which typically provides sufficient amplification for tuning over approximately 10% of its central wavelength. For example, a semiconductor gain medium centered at 1500 nm is generally limited to a tuning range of around 150 nm. Such a restricted tuning range can be insufficient for advanced optical applications, where broader spectral coverage is required to achieve expanded measurement capabilities.

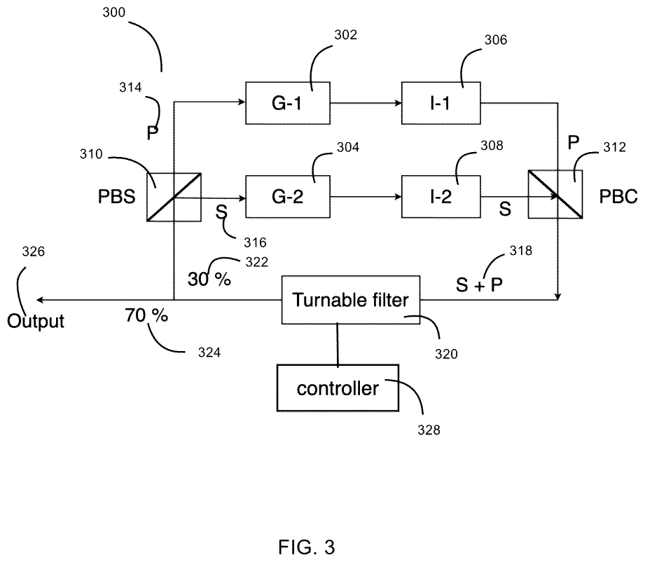

FIG. 3 illustrates a dual-band tunable ring laser system 300, which is configured to operate with two gain media, G-1 and G-2, arranged in parallel, to cover two bands of wavelengths through polarization multiplexing technique. The two bands are not necessarily consecutive.

The configuration shown in FIG. 3 can achieve a wider wavelength tuning range by integrating 2 gain media within a single laser. For one embodiment, Gain medium G-1 302 is configured to cover the wavelength range between λ₀ and λ₁, while gain medium G-2 304 covers the range between λ₁ and λ₂. This arrangement allows for a seamless transition between different wavelength bands, significantly expanding the tuning range. In some embodiments, these different bands can be non-overlapping. In some other embodiments, adjacent bands can be partially overlapping.

The isolators I-1 306 and I-2 308 can be positioned immediately following the gain media G-1 302 and G-2 304, respectively. These isolators are configured to ensure unidirectional propagation of light within the laser cavity, thereby preventing any back reflections that could destabilize the laser operation. The use of polarization-maintained (PM) fiber to couple all components ensures that the polarization state of the light is preserved throughout the system.

PBS 310 and PBC 312 are configured to manage the light paths of orthogonal polarizations. PBS 310 is designed to split the light beams based on their polarization states, directing P-polarized light along one path and S-polarized light along another. Conversely, PBC 312 combines these orthogonally polarized light beams into a single output path. This configuration allows for the efficient combination and separation of light from the different gain media, facilitating the ultra-wide tuning range.

The polarized beams, P 314 and S 316, are directed through PBC 312, where they are combined into a single beam 318. This combined beam then passes through the tunable filter 320, which is configured to select the desired lasing wavelength from the combined optical signal. The tunable filter 320 can determine the specific wavelength at which the laser will operate, allowing for precise control over the output wavelength.

The controller 328 can manage the tunable filter to achieve precise wavelength tuning according to one embodiment. The tunable filter 320 may include a cavity length modulator that adjusts the optical length of the laser cavity. The controller 328 is configured to tune the tunable filter to a desired wavelength and control the cavity length modulator

In some embodiments, the functionality of the controller can be enhanced by integrating a capacitance proximity detector and a capacitance-to-wavelength look-up table or mapper. The proximity detector is capable of measuring the capacitance between the membrane of the Fabry-Perot filter and a stationary electrode. This capacitance measurement is utilized to determine the current wavelength of operation of the tunable filter, enabling the controller to adjust the system without reliance on an optical reference signal. This method provides a compact and efficient means of wavelength control, facilitating operation of the laser system at the desired wavelength with minimal mode-hopping and optimal power output.

A Fabry-Perot filter, or Fabry-Perot cavity, is an optical device comprising two parallel partially reflecting surfaces, which create multiple reflections of light between them. This configuration allows the filter to selectively transmit certain wavelengths of light while reflecting others, based on the interference of light waves. The specific wavelengths transmitted through the Fabry-Perot filter depend on the optical path length between the reflectors and the refractive index of the medium between them. By adjusting the optical path length between the reflectors, the filter can be tuned to select different wavelengths in tunable laser systems.

In the feedback path, the system can be designed to direct 30% of the filtered light back to the gain media for amplification, as indicated by numeral reference 322. The remaining 70% of the light is directed towards the output beam 326, as indicated by output 324.

The semiconductor gain media, G-1 302 and G-2 304, are configured to emit light when current is injected. During a laser operation according to some embodiments of the present disclosure, only one of the gain media is active at any given time, depending on the desired lasing wavelength. This selective activation allows the system to efficiently utilize the gain bandwidth of each medium without interference.

The emitted wavelengths of G-1 302 and G-2 304 may have some overlap near λ₁. By utilizing the PBC 312 and PBS 310 and precisely controlling the timing of gain media activation, the system can achieve a tuning range that extends from λ₀ to λ₂. This results in a tuning range that is approximately twice as wide as that of a single-band laser, providing significant advantages for applications requiring broad spectral coverage.

As semiconductor gain media, G-1 302 and G-2 304 emit light when a current is injected. During laser operation, either G-1 or G-2 is active at any given time, depending on the desired lasing wavelength. In practice, the emitted wavelengths of G-1 and G-2 may overlap to certain extent. By controlling the timing of gain media activation, a tunable laser can be achieved with an extended wavelength range. This overlap ensures smooth transitions without spectral gaps, resulting in a tuning range that can be approximately twice as wide as that of a single-band laser.

To control which gain media or medium is turned on or off, the circuitry in the PCBA can be designed or programmed to function as switches. To further increase the tuning range, more gain media can be added in the Laser system. To do so, in addition to the polarization multiplexing technique, a wavelength division multiplexing (WDM) method can be introduced, to combine different wavelength bands of gain media through WDM filter.

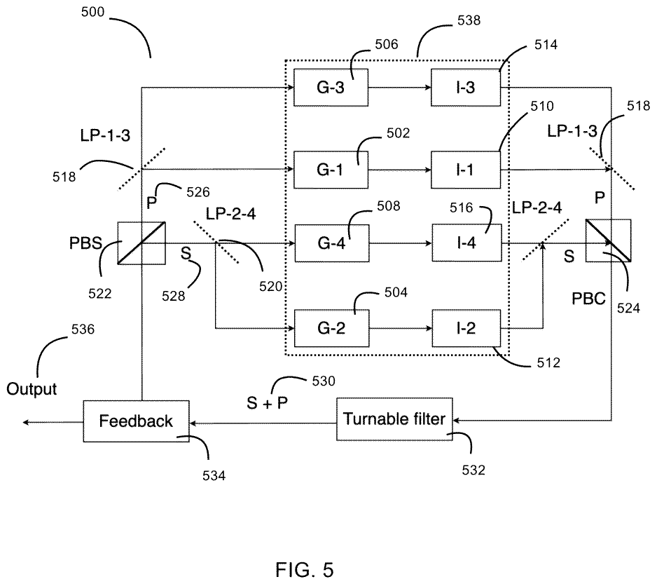

FIG. 5 is an example of a laser with four gain media combined. In this example, the WDM filters are long-pass filters. Here is how it works: G-1 and G-3 are both P-polarized and combined through long-pass filer LP-1-3. G-2 and G-4 are both S-polarized and combined through another long pass filter LP-2-4. The P and S light are merged into one beam through PCB.

In the feedback path, PBS and the 2 WDM filters send the specific wavelength of light back to the corresponding gain media.

A long-pass filter is an optical filter that transmits long-wavelength light and reflects short-wavelength light. Between the transmission band and the reflection band, there is a transition region. Therefore, when using a long-pass filter to combine two wavelength bands, the two wavelength ranges typically cannot be contiguous and must be separated by the filter's transition region.

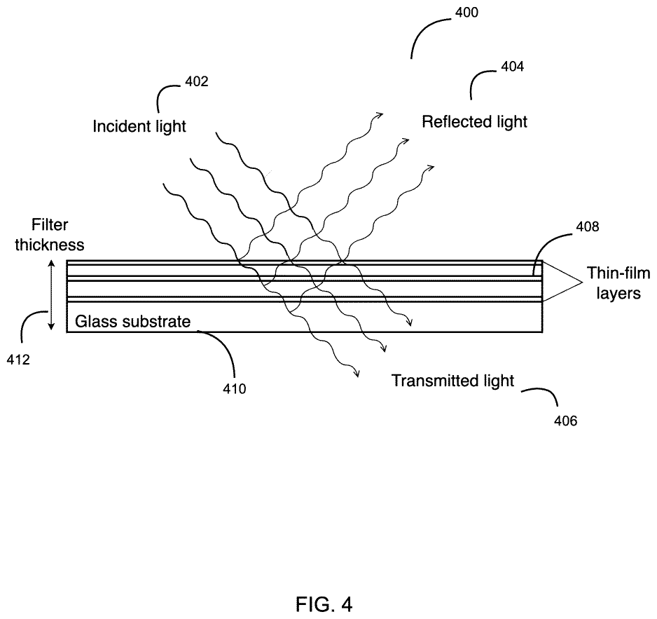

FIG. 4 illustrates a schematic structure of some embodiments of the long pass filters, specifically focusing on a thin-film interference coating structure 400, which is designed to selectively reflect and transmit specific wavelengths of light. The incident light 402 enters the filter, where it interacts with the thin-film layers 408. These layers are meticulously designed, allowing for precise control over the wavelengths that are reflected 404 and those that are transmitted 406.

FIG. 5 illustrates a quadruple-band tunable laser ring 500, which incorporates four distinct gain media, each corresponding to a specific wavelength zone. The optical paths of the four-gain media can be into a common path, where the tunable filter is positioned. The gain elements, labeled as G-1 502, G-2 504, G-3 506, and G-4 508, are configured to cover consecutive bands of wavelengths, thereby enabling an ultra-wide tuning range. Each gain medium is responsible for a particular wavelength zone, as shown in the examples in the following Table 1, with G-1 covering Zone-1, G-2 covering Zone-2, G-3 covering Zone-3, and G-4 covering Zone-4. 1. Each gain medium corresponds to a specific wavelength zone, as defined in the illustrative Table 1.

TABLE 1
Gain media corresponding to wavelength ranges and zones

| Gain media | Wavelength range | Zone number |
|---|---|---|
| G-1 | λ₀ to λ₁ | Zone-1 (odd zone) |
| G-2 | λ₁ to λ₂ | Zone-2 (even zone) |
| G-3 | λ₂ to λ₃ | Zone-3 (odd zone) |
| G-4 | λ₃ to λ₄ | Zone-4 (even zone) |

In the above Table 1, λ₀<λ₁<λ₂<λ₃<λ₄.

The optical isolators, labeled as I-1 510, I-2 512, I-3 514, and I-4 516, are placed to ensure unidirectional light propagation within the laser ring. These isolators prevent back reflections that could destabilize the laser operation, thereby maintaining the integrity of the lasing process. The individual isolation for each gain medium is not a requirement. Alternatively, light from different wavelength zones may be combined before utilizing an isolator in the common optical path. However, implementing isolation in the common optical path necessitates an isolator having a wider bandwidth.

Long pass filters, specifically LP-1-3 518 and LP-2-4 520, are employed to manage the optical paths of different wavelength zones. LP-1-3 reflects wavelengths in Zone-1 while transmitting those in Zone-3, and LP-2-4 reflects wavelengths in Zone-2 while transmitting those in Zone-4. This selective reflection and transmission facilitate the merging of optical paths from different gain media into a common path, thus extending the tuning range of the laser.

P-polarized light from G-1 is reflected by LP-1-3, merging with P-polarized light from G-3 before passing through the PBC into the common path. Simultaneously, S-polarized light from G-2 is reflected by LP-2-4, merging with S-polarized light from G-4, and is then reflected by the PBC into the common path.

Within the common path, a tunable filter selects the lasing wavelength, while a subsequent feedback coupler splits the light between the output and the feedback loop after passing through the feedback coupler, the light travels through the PBS, LP-1-3, and LP-2-4. The wavelengths corresponding to Zone-1, Zone-2, Zone-3, and Zone-4 are directed back to the respective gain media for amplification, initiating the next cycle in the ring cavity. During laser operations according to some embodiments of the present disclosure, only one gain medium is active at a time, determined by the lasing wavelength.

In some embodiments, the tunable filter can be positioned between feedback coupler 534 and PBC 524, as illustrated in FIG. 5, or alternatively, between PBS 522 and feedback coupler 534 in some other embodiments. Both configurations are functionally effective. A distinction between these configurations is that when the tunable filter is positioned between PBS 522 and feedback coupler 534, the Laser may exhibit greater output power, but also with increased amplified spontaneous emission (ASE) noise.

The polarized light paths, labeled as P 526 and S 528, represent the distinct channels for P-polarized and S-polarized light, respectively. These paths maintain the polarization integrity of the light as it traverses the laser cavity. The combined light path S+P 530 is where the PBC merges the polarized channels, ensuring that all the 4 wavelength zones can enter the tunable filter for wavelength selection.

The tunable filter 532 is positioned in the common optical path and is configured to select the lasing wavelength. This filter can be adjusted to pass a narrow wavelength band, thereby determining the specific wavelength at which the laser operates.

The feedback coupler 534 can play a dual role in the laser operation. It splits the filtered output into an output path and a feedback path, directing a portion of the light back to the active gain medium for amplification. This feedback mechanism ensures that the gain medium receives continuous stimulation to maintain the desired output.

The final output 536 represents the laser light that is emitted from the system. This output is characterized by its tunable wavelength range, which can span from λ₀ nm to λ₄ nm.

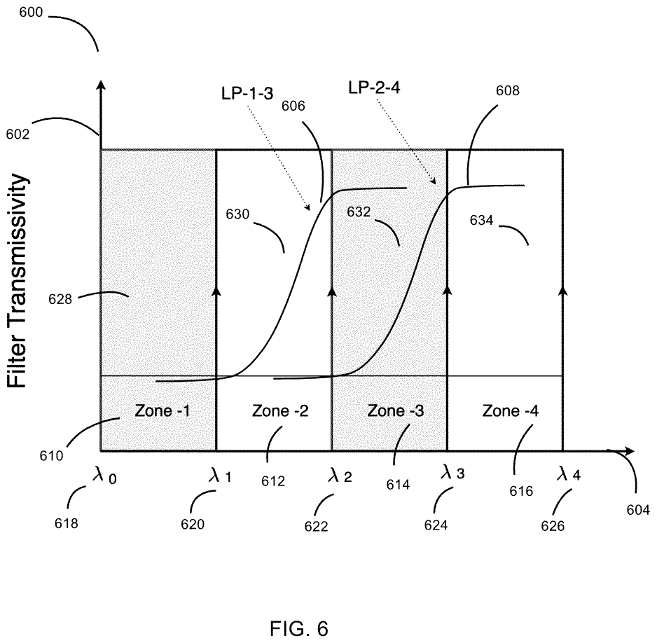

FIG. 6 illustrates a transmission spectrum of two long-pass filters, LP-1-3 and LP-2-4, which are utilized to manage light across four distinct wavelength zones: Zone-1, Zone-2, Zone-3, and Zone-4. The X-axis represents the wavelength, increasing from left to right, while the Y-axis indicates filter transmissivity, ranging from 0% (fully reflected) to 100% (fully transmitted). Each zone corresponds to a specific wavelength range that a different gain medium operates on, facilitating the ultra-wide tunable laser source.

The transmission spectrum graph 600 provides a visual representation of how the long-pass filters separate and combine the wavelength zones. The Filter Transmissivity axis 602 and the Wavelength axis 604 help to interpret the behavior of the filters in relation to the wavelength zones. The LP-1-3 curve 606 and the LP-2-4 curve 608 demonstrate the transmission characteristics of the filters, with LP-1-3 separating Zone-1 and Zone-3, and LP-2-4 separating Zone-2 and Zone-4.

Zone-1, labeled as 610, spans from wavelength λ₀ to λ₁. In this zone, light is predominantly blocked by LP-1-3, resulting in reflection. The associated gain medium for this zone is G-1. For instance, if λ₀ is 1250 nm and Mi is 1350 nm, Zone-1 covers the range from 1250 nm to 1350 nm.

Zone-2, labeled as 612, extends from wavelength Mu to 22. Light within this zone is mostly blocked by LP-2-4, leading to reflection. The gain medium associated with Zone-2 is G-2. For example, if 22 is 1450 nm, Zone-2 spans from 1350 nm to 1450 nm.

Zone-3, labeled as 614, ranges from wavelength λ₂ to λ₃. In this zone, light is transmitted by LP-1-3, allowing it to pass through after λ₂. The gain medium associated with Zone-3 is G-3. If λ₃ is 1550 nm, Zone-3 covers the range from 1450 nm to 1550 nm.

Zone-4, labeled as 616, extends from wavelength λ₃ to λ₄. Light in this zone is transmitted by LP-2-4, passing through after λ₃. The gain medium associated with Zone-4 is G-4. If λ₄ is 1650 nm, Zone-4 spans from 1550 nm to 1650 nm.

LP-1-3 reflects Zone-1 and transmits Zone-3, with transitions between λ₁ and λ₂. Conversely, LP-2-4 reflects Zone-2 and transmits Zone-4, with transitions between λ₂ and λ₃. This selective transmission and reflection of a single long-pass filter can enable the combination of two different wavelength zones into a single optical path or vice versa. With multiple long-pass filters arranged in a cascade, the system is configured to combine a plurality of different wavelength zones into a single optical path, or separate a single optical path containing multiple wavelength zones into separate wavelength zones.

The system can operate by processing P-polarized light from odd zones (Zone-1 and Zone-3) with LP-1-3 and S-polarized light from even zones (Zone-2 and Zone-4) with LP-2-4. After passing through the LP filters, the beams are merged using a PBC. The light then passes through a Tunable Filter to select the desired wavelength, with feedback paths using reverse flow through PBS and the LP filters to direct light back to the appropriate gain media.

In some applications, the tunable laser source can achieve a tuning range from 1250 nm to 1650 nm, as demonstrated in a real-world example. However, the tunable range is not limited to these wavelengths and can be extended further depending on the design and materials used in the laser system.

When the number of gain media exceeds four, the same technique can be applied to combine the spectra from multiple gain media. The odd-numbered wavelength zones operate with P-polarization, while the even-numbered wavelength zones operate with S-polarization. Wavelength zones with the same polarization are combined using WDM filters, forming two optical paths: one P-polarized stream and one S-polarized stream. These two streams are then merged using a polarization beam combiner (PBC). In general, there is no restriction on the number of wavelength zones assigned to each polarization.

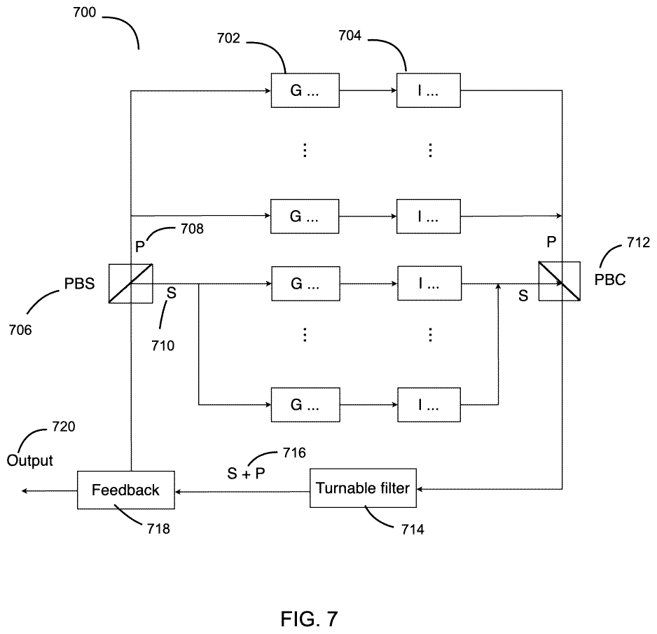

FIG. 7 illustrates a tunable ring laser with more than four gain media, designed to cover multiple consecutive wavelength bands. The tunable ring laser with more than four media 700 is configured to integrate several gain media blocks 702, each responsible for a distinct wavelength zone, thereby enabling an ultra-wide tuning range. The gain media blocks 702 are arranged in parallel and are selectively activated to emit light upon electrical current injection. This configuration allows the laser to achieve a tunable wavelength range determined by the summation of the various gain media.

The isolator blocks 704 are positioned within the tunable ring laser 700 to ensure unidirectional light propagation, thereby preventing feedback that could destabilize the laser operation.

The PBS 706 and the PBC 712 facilitate the management of optical paths by separating and combining light based on its polarization state. The PBS 706 is configured to split the incoming light into P-polarized signals 708 and S-polarized signals 710, directing them along different paths. Conversely, the PBC 712 merges these orthogonally polarized signals into a common path.

The tunable filter 714 is positioned within the common optical path of the tunable ring laser 700. It is configured to selectively pass a narrow wavelength band from the combined S and P signals 716, thereby determining the lasing wavelength. The tunable filter is configured to achieve precise wavelength selection and enable the laser wavelength to be tuned over a wide wavelength range.

The feedback coupler 718 splits the filtered light into an output path and a feedback path. A portion of the light is directed back to the active gain medium for amplification.

The output 720 of the tunable ring laser 700 is the culmination of the carefully managed optical paths and gain media activation.

The diagram of the tunable ring laser 700 demonstrates that scalability is achieved by applying the same parallelization techniques to incorporate a potentially unlimited number of gain media into a unified EGM.

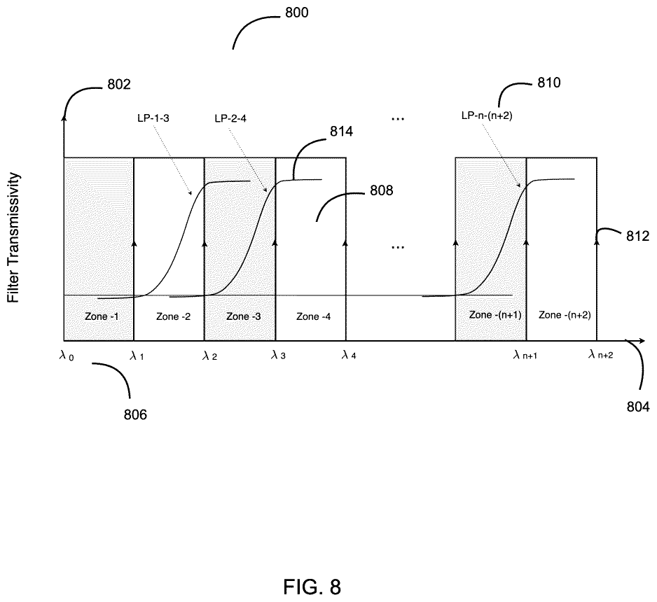

FIG. 8 illustrates the transmission spectrum of the long-path filter with more than four gain media, demonstrating the spectral design approach used to scale a multi-band tunable laser system beyond four gain media. The transmission spectrum 800 is depicted with a vertical axis representing filter transmissivity 802 and a horizontal wavelength axis 804. The spectrum is divided into distinct wavelength ranges 806, each corresponding to a specific zone 808, such as Zone-1, Zone-2, and so on, up to Zone-(n+2). Long-pass filters 810, such as LP-1-3, LP-2-4, and LP-n−(n+2), are employed to merge optical paths associated with odd and even-numbered wavelength zones. These filters are designed to transmit higher wavelength zones while reflecting lower ones, enabling the combination of parallel optical paths into a common filter path.

The spectrum illustrated in FIG. 8 allows for the integration of more than four gain media, maintaining spectral continuity and polarization separation. Each gain medium is assigned a corresponding wavelength zone, denoted as Zone-1, Zone-2, Zone-3, etc., covering respective spectral intervals defined by boundaries λ₀, λ₁, λ₂, . . . λₙ₊₂. The use of polarization-maintained paths and long-pass filters ensures that each gain medium's output is selectively combined into a shared optical path. Odd-number and even-number zones are assigned to the orthogonal polarization state.

In an illustrative embodiment, a combination of the outputs of the gain media corresponding to Zone-1, Zone-3, and Zone-5 may be achieved utilizing two long-pass filters. In a first step, a long-pass filter LP-1-3 may be used to combine the outputs of the gain media corresponding to Zone-1 and Zone-3 to form a first combined beam B13. Then, in a subsequent step, a second long-pass filter LP-3-5 may be used to combine the output of the gain medium corresponding to Zone-5 and the first combined beam B13. In this example, the long-pass filter LP-3-5 is configured to transmit the spectral interval corresponding to Zone-5 while reflecting the spectral intervals corresponding to Zone-1 and Zone-3 (or beam B13).

The use of long-pass filters, combined with PBCs and PBSs, ensures that the optical paths of different wavelength zones are efficiently merged and split, facilitating a seamless transition between different gain media.

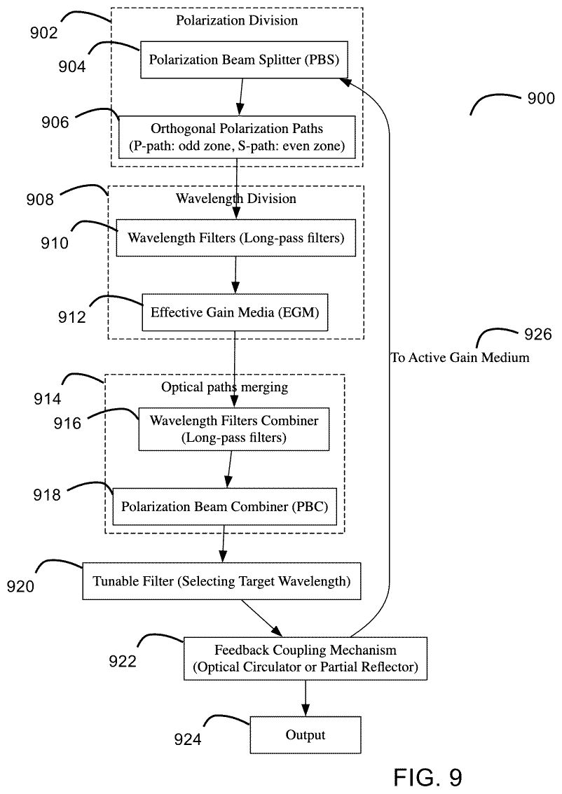

FIG. 9 illustrates a method for operating an ultra-wide-wavelength tunable laser system, emphasizing the integration of parallel-positioned gain media (e.g., EGM) and the combined use of polarization management and wavelength-filtering techniques. A wavelength-division multiplexing (WDM) filter includes a transition region and therefore is suitable for combining two wavelength bands that are separated by a spectral gap. In contrast, a polarization beam combiner (PBC) has no wavelength restriction, provided that the combined optical signals have orthogonal polarizations.

Polarization division module 902 illustrates the configuration to manage the initial separation of light into distinct polarization paths. This module facilitates the division of light into P-polarization and S-polarization paths, which are advantageous for subsequent wavelength filtering and gain media activation processes. The incoming light is split into polarization-separated paths using a PBS 904, generating two orthogonal paths: the P-polarization path and the S-polarization path, each containing non-contiguous wavelength zones.

Wavelength division module 908 illustrates using the wavelength filter to split light by wavelength into designated gain media. The wavelength filters 910, such as long-pass filters, are configured to direct light into the corresponding gain media 912. Each gain medium may amplify light within a specific wavelength zone, enabling the system to cover a wide range of wavelengths.

Optical paths merging module 914 is achieved through the use of the wavelength filtering combiner 916, such as long-pass filters, which are configured to combine outputs from the gain media. This process ensures that light from different gain media but the same polarization merges into a single optical path, ready for further processing by PBC 918 to combine the P-polarized and S-polarized light into a single output beam, facilitating feed into subsequent tunable filter modules for wavelength selection.

Tunable filter 920 is positioned in the common optical path and is configured to select the target lasing wavelength. The tunable filter's ability to select a selected wavelength output from the combined signals supports maintaining the desired lasing characteristics.

Feedback coupling mechanism 922 is configured to direct a portion of the filtered output back to the active gain medium 926. As discussed throughout the preset disclosure EGM refers to the concept where multiple gain media and corresponding isolators are placed in parallel to function as a single, unified gain medium from the perspective of the laser system.

Output 924 of the system is configured to deliver a tunable laser light, with a tunable range much larger than from an individual gain medium. This is facilitated by the controller configured to selectively activate at least one gain medium corresponding to the selected lasing wavelength, wherein the plurality of gain media collectively form an effective gain medium providing a tunable wavelength range exceeding that of any individual gain medium among the plurality of gain media.

The first separation stage uses a PBS to divide light into distinct optical paths, each corresponding to an orthogonal polarization state.

Within each polarization path, a second stage separation is performed using wavelength-selective optical filters, such as long-pass, short-pass, or band-pass filters.

On the recombination side, the output light signals from gain media with the same polarization are first merged using wavelength-selective combiners.

A PBC reunites the separately filtered and wavelength-combined beams from orthogonal polarization paths into a single output channel. This dual-axis approach, utilizing both wavelength and polarization degrees of freedom, enables broader tunability, and avoids spectral crosstalk.

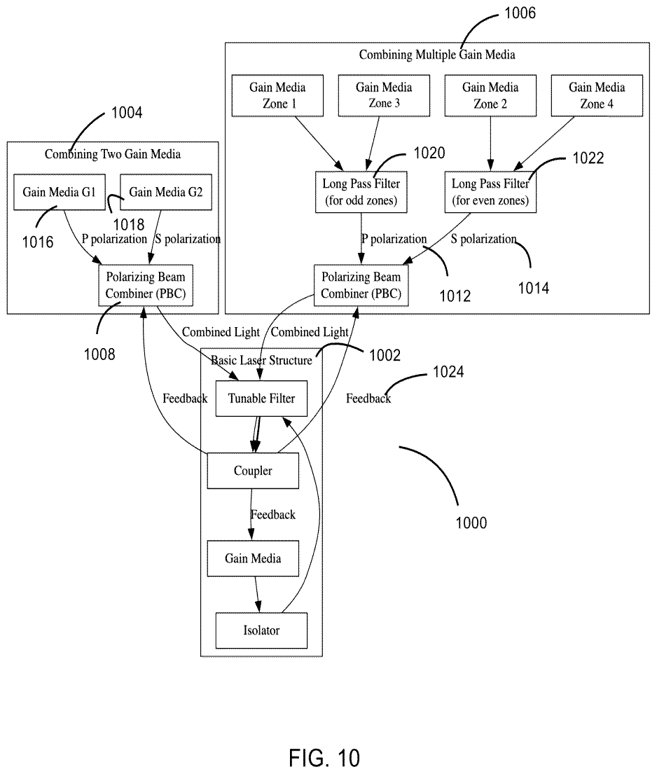

FIG. 10 illustrates a comprehensive diagram of various laser systems, including a basic laser structure, dual-band laser, and four gain media. The multi-band laser systems are implied, although not explicitly shown. The diagram provides a visual representation of the components and configurations involved in some embodiments of the present disclosure.

Laser systems 1000 encompass several elements, illustrating the overall concept and functionality of the tunable laser sources.

Basic laser structure 1002 depicted in FIG. 10 includes components such as gain media, isolators, tunable filters, and couplers. The gain media are configured to emit light, while the isolator ensures unidirectional light travel, akin to a diode for light. The tunable filter is designed to select specific wavelengths, and the coupler splits off some light as output while sending the rest back into the cavity. This configuration facilitates the feedback and amplification process, building up the selected wavelength into a strong laser beam. The tuning range is primarily limited by the gain medium's natural bandwidth.

In the dual-band laser configuration 1004, two gain media, G1 and G2, are utilized. G1 covers a wavelength range from λ₀ to λ₁ and G2 covers from λ₁ to λ₂. A PBC is employed to manage the optical paths, reflecting S-polarized light and transmitting P-polarized light. This setup allows the combination of light from G1 and G2 into a single path within the cavity.

The multi-gain media configuration 1006 introduces a more complex system with four gain media, G1, G2, G3, and G4, each covering distinct wavelength bands. The system is designed to manage these bands using long-pass filters, which selectively reflect or transmit specific wavelength ranges. This approach allows for the combination of multiple gain media into a single optical path, significantly expanding the tuning range.

PBC 1008 facilitates the combination of orthogonally polarized light from different gain media. By transmitting P-polarized light and reflecting S-polarized light, the PBC enables the merging of optical paths into a common path where the tunable filter is positioned.

P Polarization 1012 and S Polarization 1014 labels indicate the polarization states of light emitted by the gain media.

Gain Media G1 1016 and Gain Media G2 1018 are configured to emit light upon electrical current injection, as controlled by the system's controller. Each gain medium corresponds to a specific wavelength zone. The sequential activation of these gain media, based on the desired lasing wavelength, allows for a continuous tuning range that extends beyond the limitations of a single gain medium.

Long Pass Filter for odd zones 1020 and Long Pass Filter for even zones 1022 are employed to manage the optical paths of different wavelength zones.

Feedback loop 1024 directs a portion of the filtered light back to the active gain medium for amplification.

As such, various embodiments of the present disclosure provide a versatile and high-performance tunable laser source that addresses the limitations of traditional semiconductor external cavity designs and offers significant improvements in tuning range, scalability, and application versatility.

For example, the tunable laser source can achieve an ultra-wide wavelength tuning range by incorporating multiple gain media arranged in parallel. Polarization-maintained fibers, polarization beam combiners (PBC), polarization beam splitters (PBS), and wavelength division filters can be employed to manage polarized light beams of different wavelengths to combine or separate. In one configuration, dual-gain media are combined to double the tuning range compared to single-band systems. In another configuration, four gain media cover distinct wavelength regions and are merged into a common optical path for tuning across the near-infrared range. In further extensions, more than four gain media are arranged such that odd- and even-numbered wavelength zones are combined separately and merged through polarization management. One gain medium can be activated at a time during operation to ensure stable lasing, although in some other embodiments more than one gain medium can be activated at the same time. An optical device having a combining architecture can combine multiple optical paths into the common optical path. A scalable solution can be realized to achieve broad tunability, supporting applications such as optical coherence tomography, spectroscopy, and fiber sensing.

The foregoing description is provided for purposes of illustration and explanation only and is not intended to limit the scope of the present disclosure.

Various modifications, combinations, and variations of the disclosed embodiments will be apparent to those skilled in the art in view of the present disclosure, and are intended to fall within the scope of the appended claims.

Unless otherwise stated, the terms “including,” “includes,” and “include” are used in an open-ended sense.

What is claimed is:

1. A tunable laser system, comprising:
a plurality of gain media arranged in a plurality of optical paths, each gain medium being configured to provide optical gain over a respective wavelength band;
an optical device configured to combine optical signals from the plurality of gain media into a common optical cavity path shared by the plurality of gain media, using at least one optical multiplexing mechanism selected from wavelength-division multiplexing or polarization-division multiplexing;
a wavelength-selective tunable filter disposed in the common optical cavity path and configured to select a lasing wavelength;
a feedback path configured to return at least a portion of a filtered optical signal from the common optical cavity path to at least one selected gain medium of the plurality of gain media to sustain laser oscillation; and
a controller configured to selectively activate at least one gain medium corresponding to the selected lasing wavelength,
wherein individual gain media of the plurality of gain media are associated with respective feedback paths or sub-loops that intersect the common optical cavity path at the wavelength-selective tunable filter, such that the plurality of gain media collectively operate as a single effective optical cavity providing a tunable wavelength range exceeding that of any individual gain medium among the plurality of gain media.

2. The tunable laser system of claim 1, wherein only one of the plurality of gain media is activated at any given time based on the selected lasing wavelength.

3. The tunable laser system of claim 1, wherein each of the plurality of gain media comprises a semiconductor optical amplifier or a semiconductor laser gain chip configured to emit light in response to an injected electrical current.

4. The tunable laser system of claim 1, wherein each of the plurality of gain media corresponds to a different wavelength band, and wherein at least two of the wavelength bands partially overlap.

5. The tunable laser system of claim 1, wherein the plurality of gain media are optically interconnected through one or more optical paths comprising at least one of optical fiber or free-space coupling.

6. The tunable laser system of claim 5, wherein the one or more optical paths comprise polarization-maintaining optical fibers.

7. The tunable laser system of claim 5, wherein the one or more optical paths comprise free-space optical coupling.

8. The tunable laser system of claim 1, wherein the optical device comprises a polarization beam splitter and a polarization beam combiner configured to separate and merge optical signals having orthogonal polarization states.

9. The tunable laser system of claim 8, wherein the optical device further comprises one or more wavelength-selective filters configured to combine or separate optical signals from the plurality of gain media based on wavelength.

10. The tunable laser system of claim 9, wherein the plurality of gain media are assigned to odd-numbered wavelength bands and even-numbered wavelength bands, and wherein wavelength bands having a same polarization state are combined using wavelength-selective filters to form a polarized channel.

11. The tunable laser system of claim 10, wherein an odd-band polarized channel and an even-band polarized channel are merged into the common tunable cavity path using the polarization beam combiner.

12. The tunable laser system of claim 11, wherein the feedback path comprises a polarization beam splitter and wavelength-selective filters configured to route the filtered optical signal back to the corresponding gain medium associated with the selected wavelength band.

13. The tunable laser system of claim 1, wherein the tunable filter is positioned in the common tunable cavity path shared by all of the plurality of gain media, and wherein the plurality of optical paths are substantially parallel.

14. The tunable laser system of claim 1, further comprising an optical coupler configured to split the filtered optical signal into an output path and the feedback path.

15. The tunable laser system of claim 1, wherein the plurality of gain media comprise at least two gain media.

16. The tunable laser system of claim 15, wherein the plurality of gain media comprises at least three gain media, and additional long-pass filters configured to group output light from the plurality of gain media into odd and even channels.

17. The tunable laser system of claim 15, wherein the tunable wavelength range is between 1250 nm and 1650 nm in a near-infrared region.

18. The tunable laser system of claim 1, wherein the optical device employs both wavelength-division multiplexing and polarization-division multiplexing to construct the effective gain medium.

19. The tunable laser system of claim 1, wherein the common tunable cavity path forms a ring laser cavity.

20. The tunable laser system of claim 1, wherein the common tunable cavity path forms a standing-wave laser cavity.
